(19) United States
(12) Patent Application Publication
(10) Pub. No.: US 2013/0169884 A1
(43) Pub. Date: Jul. 4, 2013

(54) VOICE CONTROL SYSTEM AND ASSOCIATED CONTROL METHOD APPLIED TO ELECTRONIC APPARATUS

(71) Applicant: Hung-Chi Huang, Taichung City (TW)

(72) Inventor: Hung-Chi Huang, Taichung City (TW)

(73) Assignee: MStar Semiconductor, Inc., Hsinchu County (TW)

(21) Appl. No.: 13/551,722

(22) Filed: Jul. 18, 2012

(30) Foreign Application Priority Data
Jan. 2, 2012 (TW) 101100096

(51) Int. Cl. H03G 3/00; H04N 5/60

(52) U.S. Cl. 348/738; 381/107; 348/E05.122

(57) ABSTRACT

A control method for a voice control system applied to an electronic apparatus is provided. The method includes: launching a predetermined audio receiving period and lowering an output volume of the electronic apparatus when determining to receive an audio signal for controlling the electronic apparatus; receiving the audio signal and executing a corresponding command; and restoring the output volume of the electronic apparatus when the predetermined audio receiving period ends. The audio signal is for controlling the electronic apparatus.

This application claims the benefit of Taiwan application Serial No. 101100096, filed Jan. 2, 2012, the subject matter of which is incorporated herein by reference.

### BACKGROUND OF THE INVENTION

1. Field of the Invention

The invention relates in general to a control system and control method, and more particularly, to an audio control system and associated control method applied to an electronic apparatus.

2. Description of the Related Art

Most current electronic apparatuses, such as mobile phones and smart televisions, are equipped with various types of audio control which may include audio recognition. To be specific, the electronic apparatus is often capable of converting a user-originated audio signal to a corresponding command, based on which the electronic apparatus performs an associated operation.

Inevitably, the electronic apparatus with audio control sometimes fails to identify audio signals due to ambient noises and noises generated by the electronic apparatus itself. Therefore, it is an object of the present invention to increase the accuracy and efficiency of audio control, as well as the overall audio identification rate of the electronic apparatus.

### SUMMARY OF THE INVENTION

The invention is directed to an audio control system and associated control method.

An audio control method for an electronic apparatus disclosed by the present invention includes steps of: launching a predetermined audio receiving period and lowering an output volume of the electronic apparatus when determining to receive an audio signal for controlling the electronic apparatus; receiving the audio signal and executing a corresponding command; and restoring the output volume of the electronic apparatus when the predetermined audio receiving period ends. The audio signal is for controlling the electronic apparatus.

An audio control system for an electronic apparatus includes: a recording module, for receiving and storing an audio signal; a processing module, coupled to the recording module, for controlling the recoding module and storing the audio signal during a predetermined audio receiving period; and an audio playback module, coupled to the processing module, for lowering an output volume of the electronic apparatus for the predetermined audio receiving period. After receiving the audio signal, the electronic apparatus executes a command in response to the audio signal.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1A is a schematic diagram of a television with audio control.

FIG. 1B is a schematic diagram of an audio control system in a smart television.

FIG. 2 is a flowchart of an audio control method of the present invention.

FIG. 3 is a schematic diagram of another audio control system in a smart television.

### DETAILED DESCRIPTION OF THE INVENTION

In the following embodiments of the present invention, a smart television with audio control is taken as an example for illustrative purposes. It should be noted that the present invention is not limited to a smart television, and is in fact applicable to all electronic apparatuses with audio control.

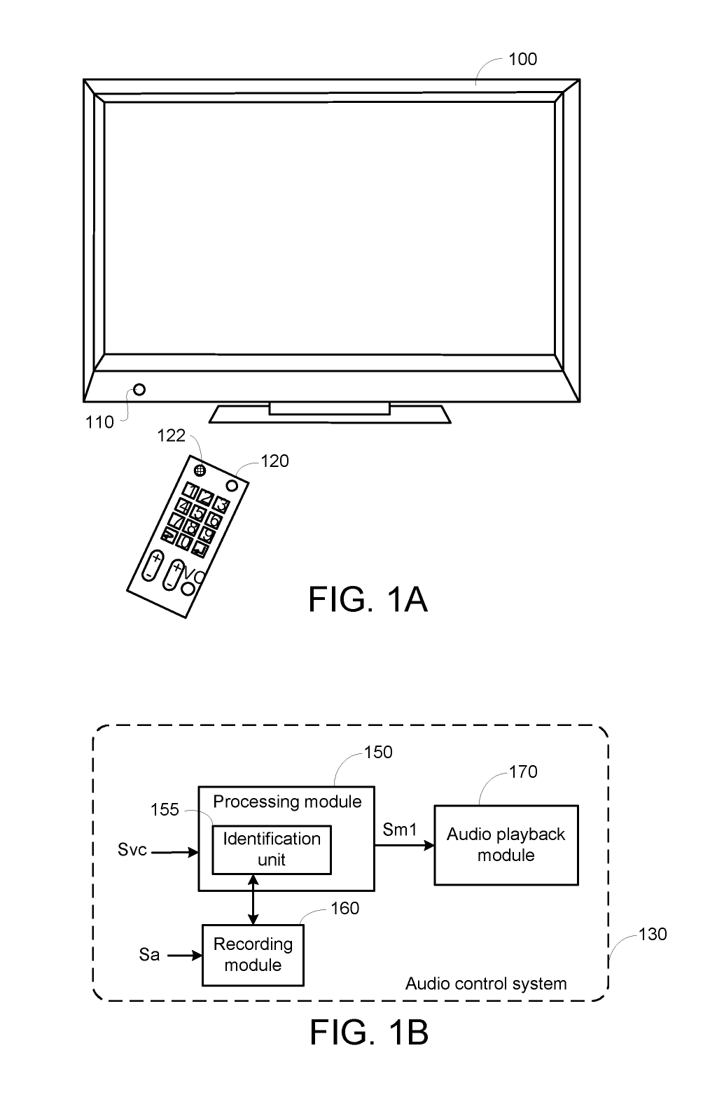

FIG. 1A shows a schematic diagram of a smart television with audio control according to an embodiment of present invention. A smart television 100 receives a user-originated sound through a microphone 110 of the smart television 100 or through a microphone 122 of a remote control 120, and generates an audio signal. The smart television 100 further includes an audio control system (not shown) for converting an audio signal to an audio command. The smart television 100 then executes the audio command to perform operations such as channel switching, volume adjustment . . . etc.

FIG. 1B shows a schematic diagram of an audio control system in a smart television. An audio system 130 includes a processing module 150, a recording module 160, and an audio playback module 170. When a user intends to proceed with audio control, the user informs the audio control system 130 through a control signal Svc that audio control is demanded, and sends out an audio signal Sa. The processing module 150 analyses whether the received signal is a control signal to determine whether to start receiving the audio signal Sa. After the audio signal Sa is generated by the microphone 110 or 112, the recording module 160 stores the audio signal Sa in the recording module 160.

The identification unit 155 in the recording module 160 then analyses the audio signal Sa in the recording module 160 and performs audio identification to generate a corresponding command. The processing module 150 executes the command to perform operations to the smart television 100, such as channel switching, volume adjustment . . . etc.

In an embodiment, assuming that the command is for adjusting the output volume of the smart television, the processing module 150 outputs a volume control signal Sm1 to the audio playback module 170. According to the volume control signal Sm1, the audio playback module 170 increases or decreases the speaker's volume of the smart television 100 to complete the corresponding operations of the command.

In general, any approach allowing a user to activate the audio control system 130 is eligible in the present invention. Taking the smart television 100 in FIGS. 1A and 1B for example, the user may press an audio control button (VC) on the remote control to generate the control signal Svc, which then activates the audio control system 130 to start receiving the audio signal Sa.

In one embodiment, in an audio receiving period (e.g., 3 seconds) after the user presses the audio control button VC to generate the control signal Svc, the audio control system 130 starts receiving the audio signal Sa. In another embodiment, in response to the user continuously pressing the audio control button (VC) to continuously generate the control signal Svc for a predetermined period, the audio control system 130 starts receiving the audio signal Sa. After the audio receiving period, the audio control system 131 stops receiving the audio signal Sa.

In an alternative embodiment, the audio control system 130 may also be activated according to a user-defined approach. For example, the user-defined approach may be a predetermined user gesture. When a sensor (e.g., an image sensor) of the smart television 100 detects the predetermined user gesture, the control signal Svc is generated to activate the audio control system 130, starting receiving the audio signal Sa. Alternatively, the user-defined approach may be a predetermined user sound. When a sensor (e.g., an image sensor) of the smart television 100 detects the predetermined user sound, the control signal Svc is generated to activate the audio control system 130, starting receiving the audio signal Sa.

To increase an identification rate of audio signals, a conventional smart television is equipped with directional microphones 110. The directional microphone is highly sensitive and noise-resistant in a predetermined direction. Further, by cooperating with a complex algorithm in an identification unit 155, the identification rate of audio signals can be increased.

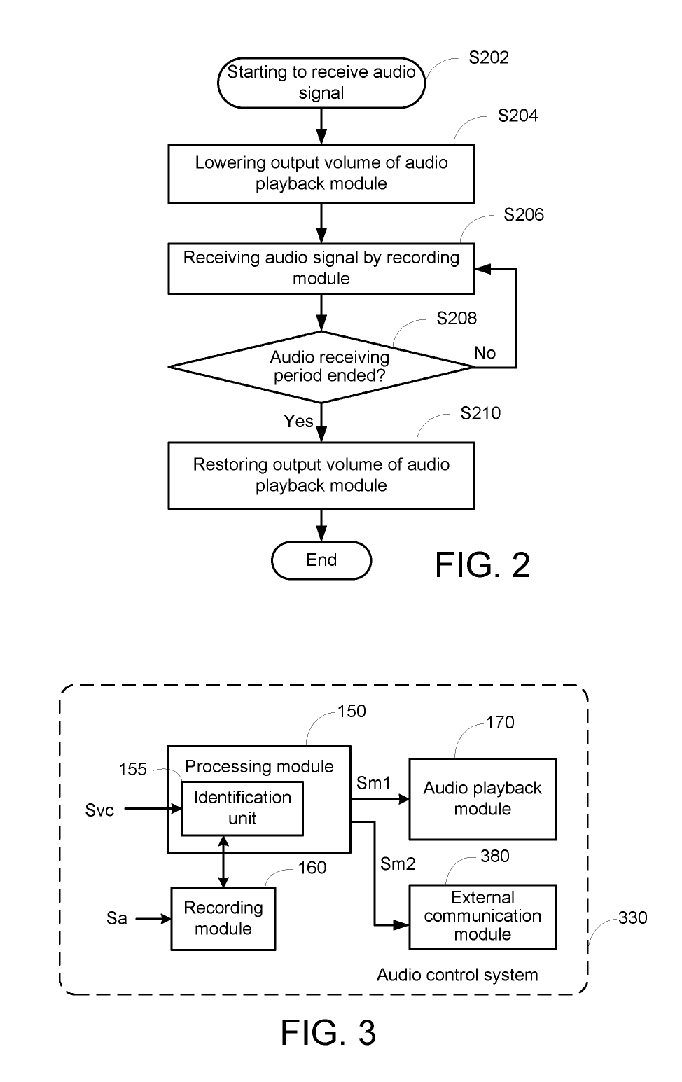

FIG. 2 shows a flowchart of an audio control method according to an embodiment of the present invention. In Step S202, the audio control system 130 starts receiving an audio signal. In Step S204, the processing module 150 lowers the output volume of the audio playback module 170 in the smart television 100. In Step S206, the recording module 160 in the audio control system 130 in the smart television 100 receives the audio signal. In Step S210, as the audio receiving period ends, the processing unit 150 restores the output volume of the audio playback module 170 in the smart television 100 and ends the audio receiving process. In contrast, the recording module 160 continues receiving the audio signal in Step S206 when the audio receiving period is not yet ended.

It can be seen from the description of FIG. 2 that, a principle of the present invention is to lower the output volume of the smart television in the audio receiving period of the audio control system. Ideally, the output sound volume of the audio playback module 170 is directly tuned to a mute state, in which the received audio signal has the highest quality. With the technique of the present invention, a smart television may adopt a common microphone that costs less while still being capable of receiving a high-quality audio signal.

Therefore, according to an embodiment of the present invention, a user may launch an audio receiving period by activating an audio control system through a control signal. In the audio receiving period, an output volume of an electronic apparatus is directly lowered or even completely muted, so as to allow the electronic apparatus to receive an optimal audio signal and to accordingly execute a corresponding command. After the sound receiving period, apart from executing the command for adjusting the output volume, the electronic apparatus restores the output volume before the audio receiving period.

In an embodiment of the present invention, besides the output volume of the electronic apparatus, the audio control module of the present invention is further capable of adjusting output volumes of devices other than the smart television. FIG. 3 shows a schematic diagram of another audio control system in a smart television. A main difference between an audio control system 330 and the audio control system 130 in FIG. 1 is that, the audio control system 330 further includes an external communication module 380. The external communication module 380 is signally connected to other devices such as a sound system, a radio, a telephone, and/or a mobile phone. In an audio receiving period, the processing module 150 further generates another audio control signal Sm2 to the external communication module 380, which then accordingly tunes the other devices to a mute state or lowers the output volumes of the other devices. That is to say, the audio signal Sa generated in the audio receiving period has the least noise interference. After the audio receiving period, the external communication module 380 controls the other devices to restore the output volumes before the audio receiving period.

As described, the present invention discloses an audio control system and associated control method applied to an electronic apparatus. An output volume of the electronic apparatus is directly lowered (or muted) in an audio receiving period, so that the electronic apparatus is able to receive an optimal audio signal to accordingly generate and execute a corresponding command.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An audio control method for an electronic apparatus, comprising:
launching a predetermined audio receiving period and lowering an output volume of the electronic apparatus when determining to receive an audio signal for controlling the electronic apparatus;
receiving the audio signal and executing a corresponding command; and
restoring the output volume of the electronic apparatus when the predetermined audio receiving period ends.

2. The audio control method according to claim 1, further comprising:
receiving the audio signal when the electronic apparatus receives a control signal that is generated by a user.

3. The audio control method according to claim 1, wherein the output volume of the electronic apparatus is adjusted to a mute state when the predetermined audio receiving period is launched.

4. The audio control method according to claim 1, wherein while a peripheral electronic apparatus being signally connected to the electronic apparatus, the method further comprising:
lowering an output volume of the peripheral electronic apparatus when the electronic apparatus is receiving the audio signal.

5. The audio control method according to claim 1, wherein the electronic apparatus is a smart television.

6. An audio control system applied in an electronic apparatus, comprising:
a recording module, for receiving and storing an audio signal;
a processing module, coupled to the recording module, for controlling the recording module and storing the audio signal during a predetermined audio receiving period; and
an audio playback module, coupled to the processing module, for lowering an output volume of the electronic apparatus for the predetermined audio receiving period;
wherein, the electronic apparatus executes a command in response to the audio signal.

7. The audio control system according to claim 6, wherein the audio playback module restores the output volume of the electronic apparatus when the predetermined audio receiving period ends.

8. The audio control system according to claim 6, further comprising:
an external communication module, signally connected to the processing module and a slave electronic apparatus, for lowering an output volume of the slave electronic apparatus when launching the predetermined audio receiving period.

9. The audio control system according to claim 6, wherein the electronic apparatus further comprises a remote control, and the control signal is generated when an audio control button on the remote control is pressed.

10. The audio control system according to claim 6, wherein the electronic apparatus further comprises a microphone for generating the audio signal.

11. The audio control system according to claim 10, wherein the microphone is disposed on a remote control.

12. The audio control system according to claim 6, wherein the electronic apparatus is a smart television.
